(19) United States
(12) Patent Application Publication
(10) Pub. No.: US 2026/0173601 A1
(43) Pub. Date: Jun. 18, 2026

(54) Display Apparatus Having Light-Emitting Devices and Pixel Lenses

(71) Applicant: LG Display Co., Ltd., Seoul (KR)

(72) Inventors: Bo A. Jin, Paju-si (KR); Seung Kwang Roh, Paju-si (KR); Woo Chul Choi, Paju-si (KR); Sang Kyoung Moon, Paju-si (KR); Dong Il Choi, Paju-si (KR); Jung Mo Cho, Paju-si (KR); Chi Hak Lee, Paju-si (KR); Min Gue Shin, Paju-si (KR)

(21) Appl. No.: 19/358,329

(22) Filed: Oct. 14, 2025

(30) Foreign Application Priority Data
Dec. 13, 2024 (KR) 10-2024-0186027

(51) Int. Cl. H10H 20/855; H10H 29/37

(52) U.S. Cl. CPC H10H 20/855; H10H 29/37

(57) ABSTRACT

A display apparatus including light-emitting devices and pixel lenses is provided. The light-emitting devices and the pixel lenses can be disposed on emission areas of a device substrate. The pixel lenses can include first pixel lenses having a lens central point spaced apart from an emission central portion of the corresponding emission area, and second pixel lenses having a lens central point overlapping with an emission central portion of the corresponding emission area. A second display area in which the second pixel lenses are disposed can surround a first display area in which the first pixel lenses are disposed. Thus, in the display apparatus, the decrease in the quality of the image provided to the user due to the installed location can be prevented.

### CROSS-REFERENCE TO RELATED APPLICATION

This application claims the benefit of Republic of Korea Patent Application No. 10-2024-0186027, filed on Dec. 13, 2024, which is hereby incorporated by reference in its entirety.

### BACKGROUND

### Field of Technology

The present disclosure relates to a display apparatus in which a light-emitting device and a pixel lens are stacked on each emission area.

### Discussion of the Related Art

Generally, a display apparatus provides an image to a user. For example, the display apparatus can include light-emitting devices. Each of the light-emitting devices can emit light displaying a specific color. For example, each of the light-emitting devices can include a light-emitting unit between a lower electrode and an upper electrode.

The light-emitting devices can be disposed on emission areas of a device substrate. Pixel lenses can be disposed on the light-emitting devices.

### SUMMARY

Accordingly, the present disclosure is directed to a display apparatus that substantially obviates one or more problems due to limitations and disadvantages of the related art.

An object of the present disclosure is to provide a display apparatus capable of preventing the decrease in the quality of the image due to the installed location.

Another object of the present disclosure is to provide a display apparatus capable of improving the quality of the image recognized in an inclined direction.

Additional advantages, objects, and features of the disclosure will be set forth in part in the description which follows and in part will become apparent to those having ordinary skill in the art upon examination of the following or may be learned from practice of the disclosure. The objectives and other advantages of the disclosure may be realized and attained by the structure particularly pointed out in the written description and claims hereof as well as the appended drawings.

To achieve these objects and other advantages and in accordance with the purpose of the present disclosure, as embodied and broadly described herein, there is provided a display apparatus comprising: a first light-emitting device on a first display area of a device substrate, the first light-emitting device overlapping with a first emission area of the first display area; a second light-emitting device on a second display area of the device substrate, the second light-emitting device overlapping with a second emission area of the second display area; an optical insulating layer on the first light-emitting device and the second light-emitting device, the optical insulating layer overlapping with the first display area and the second display area; a first pixel lens on the optical insulating layer of the first display area, the first pixel lens including a region overlapping with the first emission area; and a second pixel lens on the optical insulating layer of the second display area, the second pixel lens including a region overlapping with the second emission area, wherein a first lens central point of the first pixel lens is spaced apart from a first virtual line passing through a first emission central portion of the first emission area in a direction perpendicular to an upper surface of the device substrate toward the optical insulating layer, and wherein a second lens central point of the second pixel lens is disposed on a second virtual line passing through a second emission central portion of the second emission area in a direction perpendicular to the upper surface of the device substrate.

In one embodiment, a display apparatus comprises: a device substrate; a bank insulating layer on the device substrate, the bank insulating layer defining a first emission area in a first display area; a first light-emitting device on the first display area of the device substrate, the first light-emitting device overlapping the first emission area; an optical insulating layer on the bank insulating layer and the first light-emitting device, the optical insulating layer overlapping the first light-emitting device and the first display area; an upper barrier pattern on the optical insulating layer, the upper barrier pattern including a first upper opening overlapping with the first emission area and the first light-emitting device; and a first pixel lens on the upper barrier pattern, the first pixel lens including a region overlapping with the first upper opening, wherein the first pixel lens includes a first edge and a second edge opposite to the first edge, wherein an amount of overlap between a first pattern region of the upper barrier pattern and the first edge of the first pixel lens is different from an amount of overlap between a second pattern region of the upper barrier pattern and the second edge.

In one embodiment, a display apparatus comprises: a substrate having a first display area including a first emission area and a second display area including a second emission area; a first light emitting device overlapping with the first emission area; a second light emitting device overlapping with the second emission area; a first pixel lens overlapping the first light emitting device and the first emission area; and a second pixel lens overlapping the second light emitting device and the second emission area; wherein a center of the first pixel lens is offset from a center of the first emission area in a plan view of the display apparatus and a center of the second pixel lens overlaps a center of the second emission area in the plan view.

### BRIEF DESCRIPTION OF THE DRAWINGS

The accompanying drawings, which are included to provide a further understanding of the present disclosure and are incorporated in and constitute a part of this application, illustrate embodiment(s) of the present disclosure and together with the description serve to explain the principle of the present disclosure. In the drawings:

FIG. 1 is a view schematically showing a location where a display apparatus according to an embodiment of the present disclosure is installed;

FIG. 2 is a view showing a display panel in the display apparatus according to an embodiment of the present disclosure;

FIG. 3 is a view showing a circuit of a pixel area in the display apparatus according to an embodiment of the present disclosure;

FIG. 4 is an enlarged view of K1 region in FIG. 2 according to an embodiment of the present disclosure is installed;

FIG. 5 is a view showing cross-sections taken along I-I′ and II-II′ of FIG. 4 according to an embodiment of the present disclosure is installed;

FIG. 6 is an enlarged view of R1 region and R2 region in FIG. 5 according to an embodiment of the present disclosure is installed;

FIG. 7 is a graph showing simulation results of the luminance according to the azimuth of light emitted from a first emission area in the display apparatus according to an embodiment of the present disclosure;

FIG. 8 is a graph showing simulation results of the luminance according to the azimuth of light emitted from a second emission area in the display apparatus according to an embodiment of the present disclosure; and

FIGS. 9 to 14 are views showing the display apparatus according to another embodiment of the present disclosure.

### DETAILED DESCRIPTION

Hereinafter, details related to the above objects, technical configurations, and operational effects of the embodiments of the present disclosure will be clearly understood by the following detailed description with reference to the drawings, which illustrate some embodiments of the present disclosure. Here, the embodiments of the present disclosure are provided in order to allow the technical sprit of the present disclosure to be satisfactorily transferred to those skilled in the art, and thus the present disclosure may be embodied in other forms and is not limited to the embodiments described below.

In addition, the same or extremely similar elements may be designated by the same reference numerals throughout the specification and in the drawings, the lengths and thickness of layers and regions may be exaggerated for convenience. It will be understood that, when a first element is referred to as being “on” a second element, although the first element may be disposed on the second element so as to come into contact with the second element, a third element may be interposed between the first element and the second element.

Here, terms such as, for example, “first” and “second” may be used to distinguish any one element with another element. However, the first element and the second element may be arbitrary named according to the convenience of those skilled in the art without departing the technical sprit of the present disclosure.

The terms used in the specification of the present disclosure are merely used in order to describe particular embodiments, and are not intended to limit the scope of the present disclosure. For example, an element described in the singular form is intended to include a plurality of elements unless the context clearly indicates otherwise. In addition, in the specification of the present disclosure, it will be further understood that the terms “comprises” and “includes” specify the presence of stated features, integers, steps, operations, elements, components, and/or combinations thereof, but do not preclude the presence or addition of one or more other features, integers, steps, operations, elements, components, and/or combinations.

And, unless ‘directly’ is used, the terms “connected” and “coupled” may include that two components are “connected” or “coupled” through one or more other components located between the two components.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

### Embodiment

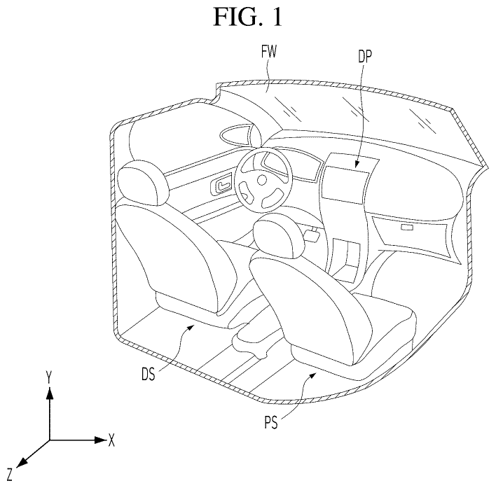

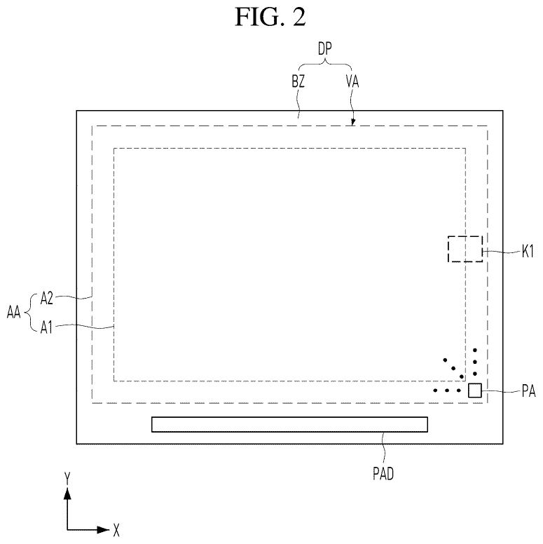

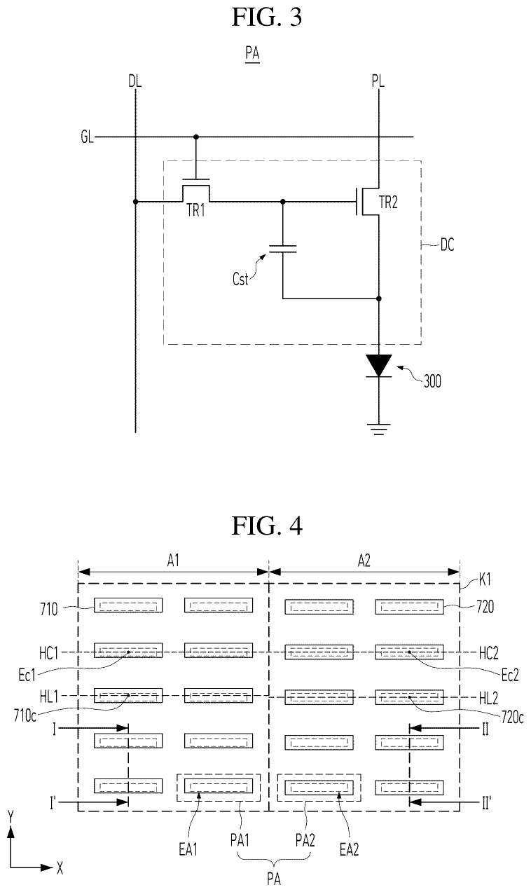

FIG. 1 is a view schematically showing a location where a display apparatus according to an embodiment of the present disclosure is installed. FIG. 2 is a view showing a display panel in the display apparatus according to the embodiment of the present disclosure. FIG. 3 is a view showing a circuit of a pixel area in the display apparatus according to an embodiment of the present disclosure.

Referring to FIGS. 1 to 3, the display apparatus according to the embodiment of the present disclosure can include a display panel DP installed in a car. The display panel DP can generate an image provided to a driver sitting in a driver seat DS of the car. For example, an image by the display panel DP can include the information necessary for the driving of the car. The image by the display panel DP can be recognized by a passenger sitting in a passenger seat PS of the car. For example, the display panel DP can be disposed between the driver seat DS and the passenger seat PS. The driver sitting in the driver seat DS and the passenger sitting in the passenger seat PS can share the image by the display panel DP.

Pixel areas PA can be disposed in the display panel DP. The pixel areas PA can be arranged in a matrix shape. For example, the pixel areas PA can be disposed side by side in a first direction X and a second direction Y that is different from (e.g., perpendicular) to the first direction X. Herein, the first direction X is a direction between the driver seat DS and the passenger seat PS. For example, a front wind-shield FW of the car can be disposed side by side with the display panel DP in the second direction Y. A third direction Z perpendicular to the first direction X and the second direction Y can be a direction toward the driver seat DS and the passenger seat PS from the display panel DP.

Various signals can be applied in each pixel area PA through signal wirings GL, DL and PL. The signal wirings GL, DL and PL can include a gate line GL applying a gate signal, a data line DL applying a data signal, and a power voltage supply line PL supplying a power voltage. In the pixel area PA, light having the luminance corresponding to the data signal can be emitted according to the gate signal by using the power voltage for one frame. For example, a driving circuit DC electrically connected to the signal wirings GL, DL and PL and a light-emitting device 300 electrically connected to the driving circuit DC can be disposed within each pixel area PA.

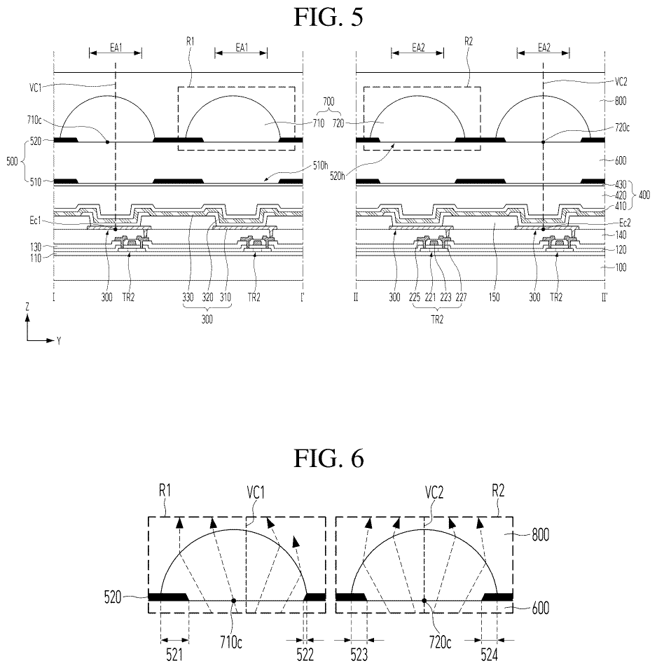

FIG. 4 is an enlarged view of K1 region in FIG. 2 according to one embodiment. FIG. 5 is a view showing cross-sections taken along I-I′ and II-II′ of FIG. 4 according to one embodiment. FIG. 6 is an enlarged view of R1 region and R2 region in FIG. 5 according to one embodiment.

Referring to FIGS. 1 to 6, in the display apparatus according to the embodiment of the present disclosure, the driving circuit DC can include a first thin film transistor TR1, a second thin film transistor TR2, and a storage capacitor Cst.

The first thin film transistor TR1 can transmit the data signal to the second thin film transistor TR2 according to the gate signal. For example, the first thin film transistor TR1 can function as a switching thin film transistor. The first thin film transistor TR1 can include a first semiconductor pattern, a first gate electrode, a first drain electrode and a first source electrode. For example, the first gate electrode can be electrically connected to the gate line GL, and the first drain electrode can be electrically connected to the date line DL.

The second thin film transistor TR2 can generate the driving current corresponding to the data signal using the power voltage. For example, the second thin film transistor TR2 can function as a driving thin film transistor. The second thin film transistor TR2 can include a second semiconductor pattern 221, a second gate electrode 223, a second drain electrode 225 and a second source electrode 227. For example, the second gate electrode 223 can be electrically connected to the first source electrode, and the second drain electrode 225 can be electrically connected to the power voltage supply line PL.

The second semiconductor pattern 221 can include a drain region electrically connected to the second drain electrode 225, a source region electrically connected to the second source electrode 227, and a channel region disposed between the drain region and the source region. The channel region of the second semiconductor pattern 221 can overlap with the second gate electrode 223. The second semiconductor pattern 221, the second drain electrode 225 and the second source electrode 227 can be insulated from the second gate electrode 223. For example, the channel region of the second semiconductor pattern 221 can have an electrical conductivity corresponding to a voltage of a signal applied to the second gate electrode 223.

A voltage of the signal applied to the second gate electrode 223 can be maintained by the storage capacitor Cst for one frame. The storage capacitor Cst can have a stacked structure of capacitor electrodes. For example, the storage capacitor Cst can include a first capacitor electrode electrically connected to the second gate electrode 233 and a second capacitor electrode electrically connected to the second source electrode 227.

The driving circuit DC of each pixel area PA can be supported by a device substrate 100. The device substrate 100 can include an insulating material. For example, the device substrate 100 can include glass or plastic. At least one insulating layer 110, 120, 130, 140 and 150 for preventing unintended electrical connection can be disposed on the device substrate 100. For example, a buffer insulating layer 110, a gate insulating layer 120, an interlayer insulating layer 130, a device planarization layer 140 and a bank insulating layer 150 can be disposed on the device substrate 100.

The buffer insulating layer 110 can prevent pollution due to the device substrate 100 in a process of forming the driving circuit DC of each pixel area PA. For example, an upper surface of the device substrate 100 toward the driving circuit DC of each pixel area PA can be covered by the buffer insulating layer 110. The first thin film transistor TR1, the second thin film transistor TR2 and the storage capacitor Cst of each pixel area PA can be disposed on the buffer insulating layer 110.

The gate insulating layer 120 can be disposed on the buffer insulating layer 110. The second gate electrode 223 of each pixel area PA can be insulated from the second semiconductor pattern 221 of the corresponding pixel area PA by the gate insulating layer 120. For example, the first semiconductor pattern and the second semiconductor pattern 221 of each pixel area PA can be covered by the gate insulating layer 120.

The interlayer insulating layer 130 can be disposed on the gate insulating layer 120. The second drain electrode 225 and the second source electrode 227 of each pixel area PA can be insulated from the second gate electrode 223 of the corresponding pixel area PA by the interlayer insulating layer 130. For example, the first gate electrode and the second gate electrode 223 of each pixel area PA on the gate insulating layer 120 can be covered by the interlayer insulating layer 130.

The device planarization layer 140 can be disposed on the interlayer insulating layer 130. The device planarization layer 140 can remove a thickness difference due to the driving circuit DC of each pixel area PA. For example, an upper surface of the device planarization layer 140 opposite to the device substrate 100 can be flat. The first drain electrode, the first source electrode, the second drain electrode 225 and the second source electrode 227 of each pixel area PA on the interlayer insulating layer 130 can be covered by the device planarization layer 140. The device planarization layer 140 can include a material having a higher fluidity than the buffer insulating layer 110, the gate insulating layer 120 and the interlayer insulating layer 130. For example, the buffer insulating layer 110, the gate insulating layer 120 and the interlayer insulating layer 130 can be an inorganic insulating layer made of an inorganic insulating material, and the device planarization layer 140 can be an organic insulating layer made of an organic insulating material.

The light-emitting device of each pixel area PA can be disposed on the upper surface of the device planarization layer 140. The light-emitting device of each pixel area PA can emit light displaying a specific color. For example, the light-emitting device 300 of each pixel area PA can include a first electrode 310, a light-emitting unit 320 and a second electrode 330, which are sequentially stacked on the device planarization layer 140.

The first electrode 310 and the second electrode 330 can include a conductive material. The second electrode 330 can include a different material from the first electrode 310. For example, the transmittance of the second electrode 330 can be higher than the transmittance of the first electrode 310. The first electrode 310 can include a material having a higher reflectance than the second electrode 330. For example, the first electrode 310 can be a reflective electrode including a metal, such as aluminum (Al) and silver (Ag), and the second electrode 330 can be a transparent electrode made of a transparent conductive material, such as ITO and IZO.

The light-emitting unit 320 can generate light having the luminance corresponding to a voltage difference between the first electrode 310 and the second electrode 330. For example, the light-emitting unit 320 can include an emission material layer (EML). The light-emitting unit 320 can have a multi-layer structure. For example, the light-emitting unit 320 can further include at least one of a hole injection layer (HIL), a hole transport layer (HTL), an electron transport layer (ETL) and an electron injection layer (EIL). The light generated by the light-emitting unit 320 can be emitted through the second electrode 330.

The first electrode 310 of each pixel area PA can be electrically connected to the driving circuit DC of the corresponding pixel area PA. For example, the first electrode 310 of each pixel area PA can be in direct contact with the second source electrode 227 of the corresponding pixel area PA by penetrating the device planarization layer 140. The bank insulating layer 150 on the device planarization layer 140 can cover a connection point between the second source electrode 227 and the first electrode 310 in each pixel area PA.

The bank insulating layer 150 can partially expose the first electrode 310 of each pixel area PA. For example, an edge of the first electrode 310 in each pixel area PA can be covered by the bank insulating layer 150. The bank insulating layer can include an insulating material. For example, the first electrode 310 of each pixel area PA can be insulated from the first electrode 310 of adjacent pixel area PA by the bank insulating layer 150. The light-emitting unit 320 can be in direct contact with a portion of the first electrode 310 exposed by the bank insulating layer in each pixel area PA. That is, in the display apparatus according to the embodiment of the present disclosure, an emission area EA1 and EA2 in which the light is emitted can be defined in each pixel area PA by the bank insulating layer 150. A region of the device substrate 100 overlapping with the bank insulating layer 150 can define as a non-emission area in which the light is not emitted.

The light emitted from the emission area EA1 and EA1 of each pixel area PA can display a different color from the light emitted from the emission area EA1 and EA2 of adjacent pixel area PA. For example, the light-emitting unit 320 of each pixel area PA can be spaced apart from the light-emitting unit 320 of adjacent pixel area PA. A signal applied to the second electrode 330 of each pixel area PA can be a same as a signal applied to the second electrode 330 of adjacent pixel area PA. For example, the second electrode 330 of each pixel area PA can be electrically connected to the second electrode 330 of adjacent pixel area PA. Thus, in the display apparatus according to the embodiment of the present disclosure, the luminance of the light emitted from the emission area EA1 and EA2 of each pixel area PA can be symmetrical to the driving current generated by the driving circuit DC of the corresponding pixel area PA. That is, in the display apparatus according to the embodiment of the present disclosure, the luminance of the light emitted from each pixel area PA can be controlled by the data signal applied to the corresponding pixel area PA. Therefore, in the display apparatus according to the embodiment of the present disclosure, the control in the luminance of the light emitted from each pixel area PA can be simplified.

An encapsulation structure 400 can be disposed on the light-emitting device of each pixel area PA. The encapsulation structure 400 can prevent or at least reduce the damage of the light-emitting device in each pixel area PA due to external impact and moisture. For example, the light-emitting device 300 of each pixel area PA can be covered by the encapsulation structure 400. The encapsulation structure 400 can extend beyond the emission area EA1 and EA2 defined in each pixel area PA. For example, the encapsulation structure 400 can include a region overlapping with the emission area EA1 and EA2 of each pixel area PA and a region overlapping with the non-emission area. The encapsulation structure 400 can have a multi-layer structure. For example, the encapsulation structure 400 can include a first encapsulating layer 410, a second encapsulating layer 420 and a third encapsulating layer 430, which are sequentially stacked. The second encapsulating layer 420 can include a material having a higher fluidity than the first encapsulating layer 410 and the third encapsulating layer 430. For example, the first encapsulating layer 410 and the third encapsulating layer 430 can be an inorganic encapsulating layer made of an inorganic insulating material, and the second encapsulating layer 420 can be an organic encapsulating layer made of an organic insulating material. A thickness difference due to the light-emitting device of each pixel area PA can be removed by the second encapsulating layer 420. For example, an upper surface of the encapsulation structure 400 opposite to the device substrate 100 can be flat.

A barrier structure 500 can be disposed on the encapsulation structure 400. The barrier structure 500 can have a multi-layer structure. For example, the barrier structure 500 can have a stacked structure of a lower barrier pattern 510 and an upper barrier pattern 520. The lower barrier pattern 510 and the upper barrier pattern 520 can include a material capable of blocking light. For example, the lower barrier pattern 510 and the upper barrier pattern can include a black dye, such as carbon black. The upper barrier pattern 520 can include a same material as the lower barrier pattern 510. Thus, in the display apparatus according to the embodiment of the present disclosure, the traveling direction of the light emitted from the emission area EA1 and EA2 of each pixel area PA can be restricted by the barrier structure 500.

The lower barrier pattern 510 can be disposed close to the encapsulation structure 400. For example, a lower surface of the lower barrier pattern 510 toward the device substrate 100 can be in direct contact with the upper surface of the encapsulation structure 400. The lower barrier pattern 510 can include lower openings 510h. Each of the lower openings 510h can overlap with the emission area EA1 and EA2 of one of the pixel areas PA. For example, the light emitted from the light-emitting device 300 of each pixel area PA can pass through one of the lower openings 510h.

The lower opening 510h of each pixel area PA can have a planar shape corresponding to the emission area EA1 and EA2 defined in the corresponding pixel area PA. A center of the lower opening 510h on each pixel area PA can overlap with an emission central portion of the emission area EA1 and EA2 defined in the corresponding pixel area PA. For example, the center of the lower opening 510h on each pixel area PA can be disposed on a virtual line VC1 and VC2 passing through the emission central portion Ec1 and Ec2 of the emission area EA1 and EA2 defined in the corresponding pixel area PA. The lower opening 510h of each pixel area PA can have a larger size than the emission area EA1 and EA2 of the corresponding pixel area PA. For example, the lower barrier pattern 510 cannot overlap with the emission area EA1 and EA2 of each pixel area PA. Thus, in the display apparatus according to the embodiment of the present disclosure, the amount of light emitted from the light-emitting device 300 of each pixel area PA and passing through the lower opening 510h of the corresponding pixel area PA can be increased.

The upper barrier pattern 520 can be disposed on the lower barrier pattern 510. The upper barrier pattern 520 can be spaced apart from the lower barrier pattern 510. For example, the lower barrier pattern 510 can be covered by an optical insulating layer 600 that is between the upper barrier pattern 520 and the lower barrier pattern 510, and the upper barrier pattern 520 can be disposed on the optical insulating layer 600. The optical insulating layer 600 can include a transparent material. For example, the optical insulating layer 600 can include an organic insulating material. The optical insulating layer 600 can include a region overlapping with the emission area EA1 and EA2 of each pixel area PA. For example, the lower openings 510h of the lower barrier pattern 510 can be filled by the optical insulating layer 600.

The upper barrier pattern 520 can be disposed on an upper surface of the optical insulating layer 600 opposite to the device substrate 100. For example, a lower surface of the upper barrier pattern 520 toward the device substrate 100 can be in direct contact with the upper surface of the optical insulating layer 600. The upper barrier pattern 520 can include upper openings 520h. The upper openings 520h can overlap with the lower openings 510h. For example, the emission area EA1 and EA2 of each pixel area PA can overlap with one of the upper openings 520h. The light emitted from the light-emitting device 300 of each pixel area PA can pass through one of the lower openings 510h and one of the upper openings 520h.

The upper barrier pattern 520 can overlap with the lower barrier pattern 510. The upper opening 520h on each pixel area PA can have a planar shape same as the lower opening 510h on the corresponding pixel area PA. For example, a plane of the upper opening 520h on each pixel area PA can be corresponding to a plane of the emission area EA1 and EA2 defined in the corresponding pixel area PA. A center of the upper opening 520h on each pixel area PA can overlap with the center of the lower opening 510h on the corresponding pixel area PA in a plane view of the display apparatus. For example, the center of the upper opening 520h on each pixel area PA can be disposed on the virtual line VC1 and VC2 passing through the emission central portion Ec1 and Ec2 of the emission area EA1 and EA2 defined in the corresponding pixel area PA in a direction perpendicular to the upper surface of the device substrate 100. The upper opening 520h of each pixel area PA can have a same size as the lower opening 510h of the corresponding pixel area PA. For example, a size of the upper opening 520h on each pixel area PA can be larger than a size of the emission area EA1 and EA2 defined in the corresponding pixel area PA. The upper barrier pattern 520 cannot overlap with the emission area EA1 and EA2 of each pixel area PA. Thus, in the display apparatus according to the embodiment of the present disclosure, the light extraction efficiency of each pixel area PA can be improved.

Pixel lenses 700 can be disposed on regions of the optical insulating layer 600 exposed by the upper barrier pattern 520. Each of the pixel lenses 700 can be disposed on one of the pixel areas PA. For example, each of the upper openings 520h can be filled by one of the pixel lenses 700. The pixel lens 700 on each pixel area PA can include a region overlapping with the emission area EA1 and EA2 defined in the corresponding pixel area PA. The pixel lens 700 of each pixel area PA can focus the light passing through the upper opening 520h of the corresponding pixel area PA. For example, a surface of each pixel lens 700 opposite to the device substrate 100 can have a convex shape.

Each of the pixel lenses 700 can include a lower surface toward the device substrate 100. The lower surface of the pixel lens 700 on each pixel area PA can be in direct contact with the upper surface of the optical insulating layer 600 within the upper opening 520h of the corresponding pixel area PA. The lower surface of the pixel lens 700 on each pixel area PA can have a larger size than the upper opening 520h of the corresponding pixel area PA. For example, an edge of the pixel lens 700 on each pixel area PA can overlap with the upper barrier pattern 520. The upper barrier pattern 520 can overlap with the edge of the pixel lens 700 on each pixel area PA.

A lens planarization layer 800 can be disposed on the pixel lens 700 of each pixel area PA. The lens planarization layer 800 can prevent or at least reduce the damage of the pixel lens 700 on each pixel area PA due to the external impact. For example, the pixel lens 700 on each pixel area PA can be completely covered by the lens planarization layer 800. The lens planarization layer 800 can extend on an upper surface of the upper barrier pattern 520 opposite to the device substrate 100. For example, the lens planarization layer 800 can include a region overlapping with the pixel lenses 700 and a region overlapping with the upper barrier pattern 520.

The lens planarization layer 800 can include an insulating material. For example, the lens planarization layer 800 can include an organic insulating material. A thickness difference due to the pixel lenses 700 can be removed by the lens planarization layer 800. For example, an upper surface of the lens planarization layer 800 opposite to the device substrate 100 can be flat. The lens planarization layer 800 can have a refractive index smaller than each pixel lens 700. Thus, in the display apparatus according to the embodiment of the present disclosure, the light passing through each pixel lens 700 can be focused by the difference in reflective indexes between the corresponding pixel lens 700 and the lens planarization layer 800.

As shown in FIG. 2, in the display apparatus according to the embodiment of the present disclosure, the display panel DP can include a display area AA in which the pixel areas PA are disposed, and a bezel area BZ disposed outside the display area AA. The bezel area BZ can extend along an edge of the display area AA. For example, the display area AA can be surrounded by the bezel area BZ.

A gate driver electrically connected to the gate line GL, a data driver electrically connected to the data line DL, and a power unit electrically connected to the power voltage supply line PL can be disposed outside the display area AA. For example, each of the signal wirings GL, DL and PL can include a region disposed on the bezel area BZ. At least one of the gate driver, the data driver and the power unit can be disposed outside the display panel DP. For example, a pad area PAD to which an external signal is applied can be disposed in the bezel area BZ. At least one of the gate signal, the data signal and the power voltage can be applied through the pad area PAD.

The display area AA can include a first display area A1 and a second display area A2 disposed outside the first display area A1. The second display area A2 can extend along an edge of the first display area A1. For example, the first display area A1 can be surrounded by the second display area A2. The first display area A1 can be disposed on a central portion of the display panel DP. For example, the second display area A2 can be disposed between the first display area A1 and the bezel area BZ.

As shown in FIGS. 4 to 6, the pixel areas PA can include first pixel areas PA1 disposed within the first display area A1 and second pixel areas PA2 disposed within the second display area A1. A first emission area EA1 can be defined in each first pixel area PA1, and a second emission area EA2 can be defined in each second pixel area PA2.

A plane of the second emission area EA2 can have a same shape as a plane of the first emission area EA1. For example, the first emission area EA1 and the second emission area EA2 can have a planar shape of a bar extending in the first direction X. Thus, in the display apparatus according to the embodiment of the present disclosure, a viewing angle of the light emitted from the first emission area EA1 and the light emitted from the second emission area EA2 can be increased in the first direction X. Therefore, in the display apparatus according to the embodiment of the present disclosure, the image displayed by the first pixel area PA1 of the first display area A1 and the second pixel area PA2 of the second display area A2 can be shared with the driver and the passenger disposed side by side inside the car in the first direction X. The second emission area EA2 can have a same size as the first emission area EA1.

The pixel lenses 700 can include a first pixel lenses 710 overlapping with the first emission area EA1 of each first pixel area PA1 and a second pixel lenses 720 overlapping with the second emission area EA2 of each second pixel area PA2. The second pixel lenses 720 can be disposed on a same layer as the first pixel lenses 710. The second pixel lenses 720 can include a same material as the first pixel lenses 710. The second pixel lens 720 can be formed by a same process as the first pixel lens 710. For example, the second pixel lenses 720 can be formed simultaneously with the first pixel lenses 710.

A first pixel lens 710 can have a planar shape corresponding to a planar shape of the first emission area EA1. For example, the first pixel lens 710 can have a planar shape of a bar extending in the first direction X. A cross-section of the first pixel lens 710 in the second direction Y can have a semi-circular shape.

A first lens central point 710c of the first pixel lens 710 can be spaced apart from a first vertical virtual line VC1 passing through a first emission central portion Ec1 of the first emission area EA1 in a direction perpendicular to the upper surface of the device substrate 100. Herein, the first lens central point 710c can mean the center of the first pixel lens 710 in the first direction X and the second direction Y, and the first emission central portion Ec1 can mean the center of the first emission area EA1 in the first direction X and the second direction Y. Thus, the center of the first pixel lens (e.g., the first lens central point 710c) is offset from a center of the first emission areas EA1 (e.g., the first emission central point Ec1) in a plan view of the display apparatus. For example, a first virtual center line HL1 can pass through the first lens central point 710c in the first direction X, a first horizontal virtual line HC1 can pass through the first emission central portion Ec1 in the first direction X, and the first virtual center line HL1 can be spaced apart (e.g., offset) from the first horizontal virtual line HC1 in the second direction Y.

A first pattern region 521 (e.g., a first region) of the upper barrier pattern 520 overlapping with a first edge of the first pixel lens 710 toward the second direction Y can have a different size from a second pattern region 522 (e.g., a second region) of the upper barrier pattern 520 overlapping with a second edge of the first pixel lens 710. The first pattern region 521 and the second pattern region 522 are around the upper opening 520h that overlaps the first emission area EA1 in the plan view. That is, the amount of overlap between the first pixel lens 710 and the first pattern region 521 is different from the amount of overlap between the first pixel lens 710 and the second pattern region 622. The second edge of the first pixel lens 710 can be opposite to the first edge of the first pixel lens 710. For example, the second pattern region 522 can have a smaller size than the first pattern region 521. Thus, in the display apparatus according to the embodiment of the present disclosure, a focusing point of the light L1 emitted from the first emission area EA1 can be moved in the second direction Y.

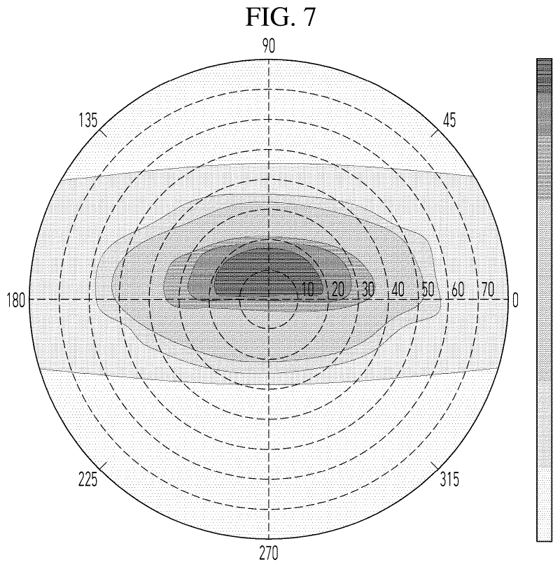

FIG. 7 is a graph showing simulation results of the luminance according to the azimuth of light L1 emitted from the first emission area EA1 of the first display area A1 in the display apparatus according to an embodiment of the present disclosure.

Referring to FIG. 7, in the display apparatus according to the embodiment of the present disclosure, the light L1 emitted from the first emission area EA1 can have the maximum luminance at the upper side of the front of the first emission area EA1 than the front of the first emission area EA1. As shown in FIG. 1, in general, the view of the driver sitting in the driver seat DS of the car can be secured through the front wind-shield FW of the car, and the display panel DP of the display apparatus installed inside the car can be installed at a lower position than the driver's face. That is, in the display apparatus according to the embodiment of the present disclosure, the focusing point of the light L1 emitted from the first emission area EA1 can move toward the face of the driver sitting in the driver seat DS of the car. Thus, in the display apparatus according to the embodiment of the present disclosure, the luminance of the image recognized by the driver through the face disposed higher than the front of the display panel DP can increase by the light L1 emitted from the first emission area EA1.

As shown in FIGS. 4 to 6, in the display apparatus according to the embodiment of the present disclosure, the second pixel lens 720 can have a planar shape corresponding to a planar shape of the second emission area EA2 of the second pixel area PA2. For example, the second pixel lens 720 can have a planar shape of a bar extending in the first direction X. A plane of the second pixel lens 720 can have a same shape as a plane of the first pixel lens 710. A cross-section of the second pixel lens 720 in the second direction Y can have a semi-circular shape. For example, the second pixel lens 720 can have a same size as the first pixel lens 710.

A second lens central point 720c of the second pixel lens 720 can be disposed on a second vertical virtual line VC2 passing through a second emission central portion Ec2 of the second emission area EA2 in a direction perpendicular to the upper surface of the device substrate 100. Herein, the second lens central point 720c can mean the center of the second pixel lens 720 in the first direction X and the second direction Y, and the second emission central portion Ec2 can mean the center of the second emission area EA2 in the first direction X and the second direction Y. Thus, the center of the second pixel lens 720 overlaps the center of the second emission area EA2 in the plan view of the display apparatus. For example, a second virtual center line HL2 passing through the second lens central point 720c in the first direction X can coincide with a second horizontal virtual line HC2 passing through the second emission central portion Ec2 in the first direction X.

The second horizontal virtual line HC2 can coincide with the first horizontal virtual line HC1. For example, the first emission central portion Ec1 can be disposed on the second horizontal virtual line HC2, the second emission central portion Ec2 and the second lens central point 720c can be disposed on the first horizontal virtual line HC1. The second virtual center line HL2 can be spaced apart from the first virtual center line HL1 in the second direction Y.

In one embodiment, the upper barrier pattern 50 can include a third pattern region 523 and a fourth pattern region 524 that are around the upper opening 520h that overlaps the second emission area EA2 in the plan view. The third pattern region 523 of the upper barrier pattern 520 overlapping with a third edge of the second pixel lens 720 can have a same size as the fourth pattern region 524 of the second pixel lens 524 of the upper barrier pattern 520 overlapping with a fourth edge of the second pixel lens 720. Thus, the amount of overlap between the third pattern region 523 and the second pixel lens 720 is the same as the amount of overlap between the fourth pattern region 524 and the second pixel lens 720. The third edge of the second pixel lens 720 can be toward the second direction Y. The fourth edge of the second pixel lens 720 can be opposite to the third edge of the second pixel lens 720. Thus, in the display apparatus according to the embodiment of the present disclosure, the focusing point of the light L2 emitted from the second emission area EA2 can be disposed on the second vertical virtual line VC2.

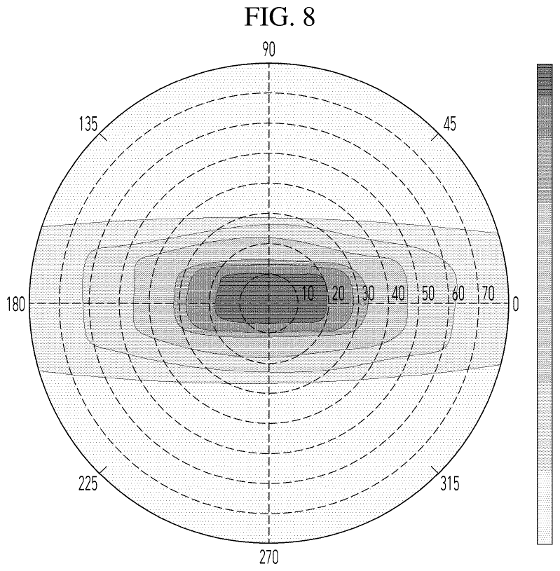

FIG. 8 is a graph showing simulation results of the luminance according to the azimuth of light L2 emitted from the second emission area EA2 of the second display area A2 in the display apparatus according to an embodiment of the present disclosure.

Referring to FIG. 8, in the display apparatus according to the embodiment of the present disclosure, the light L2 emitted from the second emission area EA2 can have the maximum luminance at the front of the second emission area EA2. Thus, in the display apparatus according to the embodiment of the present disclosure, the image provided to the driver's face by the second display area A2 surrounding the first display area A1 can have a lower luminance than the image provided to the driver's face by the first display area A1. That is, in the display apparatus according to the embodiment of the present disclosure, the deterioration of the image provided to the driver's face by the first display area A1 due to the light L2 emitted from the second emission area EA2 of the second display area A2 can be prevented or at least reduced. For example, in the display apparatus according to the embodiment of the present disclosure, an area of the second display area A2 surrounding the first display area A1 can be smaller than an area of the first display area A1. Therefore, in the display apparatus according to the embodiment of the present disclosure, the image by the first display area A1 can be clearly recognized by the driver.

Accordingly, the display apparatus according to the embodiment of the present disclosure can include the first pixel areas PA1 within the first display area A1 of the display panel DP, wherein the focusing point of the light L1 emitted from the first emission area EA1 of each first pixel area PA1 can be moved in the second direction Y from the front of the corresponding first pixel area PA1 by the first pixel lens 710. Thus, in the display apparatus according to the embodiment of the present disclosure, the luminance of the image provided to the user's face disposed in an inclined direction based on the front of the display panel DP can be increased. For example, in the display apparatus according to the embodiment of the present disclosure, the luminance of the image provided to the driver by the display panel DP installed below the driver's face in the car can be increased. Therefore, in the display apparatus according to the embodiment of the present disclosure, the decrease in the quality of the image provided to the user due to the installed location can be prevented. And, in the display apparatus according to the embodiment of the present disclosure, the low power operation can be possible, and the power consumption can be reduced.

Further, the display apparatus according to an embodiment of the present disclosure can include the second pixel areas PA2 within the second display area A2 surrounded by the first display area A1, wherein the light L2 emitted from the second emission area EA2 of each second pixel area PA2 can be focused in front of the corresponding second pixel area PA2 by the second pixel lens 720. That is, in the display apparatus according to the embodiment of the present disclosure, the luminance of the image provided to the user by the second display area A2 can be lower than the luminance of the image provided to the user by the first display area A1 in which the display panel DP is installed and the user's face is not coincide with a front surface of the display panel DP in the second direction Y. Thus, in the display apparatus according to the embodiment of the present disclosure, the image provided by the first display area A1 can be clearly recognized on the user's face disposed in an inclined direction with respect to the front surface of the display panel DP. Therefore, in the display apparatus according to the embodiment of the present disclosure, the quality of the image recognized by the user can be improved, regardless of the relative position between the user's face and the display panel DP.

The display apparatus according to the embodiment of the present disclosure is described that a distance between the first lens central point 710c and the first vertical virtual line VC1 in the second direction Y can be adjusted according to the installation location of the display panel DP. For example, in the display panel DP of the display apparatus according to the embodiment of the present disclosure installed inside the car, a virtual line connecting the first emission central portion Ec1 to the first lens central point 710c can be inclined by about 10° with respect to the first vertical virtual line VC1. Thus, in the display apparatus according to the embodiment of the present disclosure, the image by the display panel DP installed in various places can be clearly recognized by the user.

The display apparatus according to an embodiment of the present disclosure is described that the driving circuit DC of each pixel area PA comprises of the first thin film transistor TR1, the second thin film transistor TR2 and the storage capacitor Cst. However, in the display apparatus according to another embodiment of the present disclosure, the driving circuit DC of each pixel area PA can include a driving thin film transistor and at least one switching thin film transistor. For example, in the display apparatus according to another embodiment of the present disclosure, the driving circuit DC of each pixel area PA can further include a third thin film transistor to initialize the storage capacitor Cst of the corresponding pixel area PA according to the gate signal. The third thin film transistor of each pixel area PA can include a third semiconductor pattern, a third gate electrode, a third drain electrode and a third source electrode. The third semiconductor pattern of each pixel area PA can include a semiconductor material. The third gate electrode of each pixel area PA can be electrically connected to the gate line GL. The third drain electrode of each pixel area PA can be electrically connected to an initial line applying an initial signal. The third source electrode of each pixel area PA can be electrically connected to the storage capacitor Cst of the corresponding pixel area PA. Thus, in the display apparatus according to another embodiment of the present disclosure, the degree of freedom in the configuration of the driving circuit DC in each pixel area PA can be improved.

In the display apparatus according to the embodiment of the present disclosure, the location and the electric connection of the first drain electrode, the first source electrode, the second drain electrodes 225 and the second source electrode 227 in each driving circuit DC can vary depending on the configuration of the corresponding driving circuit DC and/or the type of the corresponding thin film transistors TR1 and TR2. For example, in the display apparatus according to another embodiment of the present disclosure, the second gate electrode 223 of each driving circuit DC can be electrically connected to the first drain electrode of the corresponding driving circuit DC. Thus, in the display apparatus according to another embodiment of the present disclosure, the degree of freedom in the configuration of each driving circuit DC and the type of each thin film transistor TR1 and TR2 can be improved.

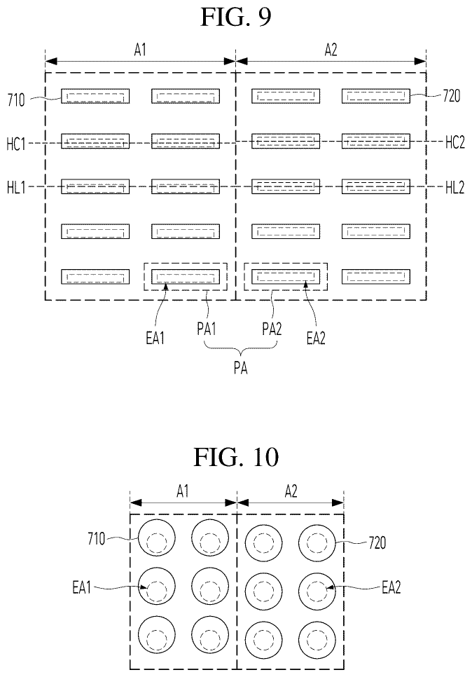

The display apparatus according to the embodiment of the present disclosure is described that the second horizontal virtual line HC2 coincides with the first horizontal virtual line HC1, and the second virtual center line HL2 is spaced apart from the first virtual center line HL1. However, in the display apparatus according to another embodiment of the present disclosure, the location of the first emission area EA1 and the second emission area EA1 and the location of the first pixel lens 710 and the second pixel lens 720 can have different relationships. For example, in the display apparatus according to another embodiment of the present disclosure, the second virtual center line HL2 can coincide with the first virtual center line HL1, and the second horizontal virtual line HC2 can be spaced apart from the first horizontal virtual line HC1 in the second direction Y, as shown in FIG. 9. That is, in the display apparatus according to another embodiment of the present disclosure, the pixel lenses 700 can be disposed side by side in the first direction X and the second direction Y, and the location of each first pixel area PA1 can be moved in the second direction Y with respect to the second pixel areas PA2. Thus, in the display apparatus according to another embodiment of the present disclosure, the degree of freedom in the relative location of the pixel areas PA and the pixel lenses 700 can be improved.

The display apparatus according to the embodiment of the present disclosure is described that each of the emission areas EA1 and EA2 and each of the pixel lenses 700 has a planar shape of a bar extending in the first direction X. However, in the display apparatus according to another embodiment of the present disclosure, a plane of each emission area EA1 and EA2 can have various shapes. For example, in the display apparatus according to another embodiment of the present disclosure, each of the emission areas EA1 and EA2 can have a plane of a circular shape. A plane of each pixel lens 710 and 720 can have a shape corresponding to a plane of the corresponding emission area EA1 and EA2, as shown in FIG. 10. In the display apparatus according to another embodiment of the present disclosure, a plane of the second emission area EA2 and a plane of the second pixel lens 720 in the second display area A2 can be concentric. Thus, in the display apparatus according to another embodiment of the present disclosure, the degree of freedom in the plane of each emission area EA1 and EA2 and the plane of each pixel lens 710 and 720 can be improved.

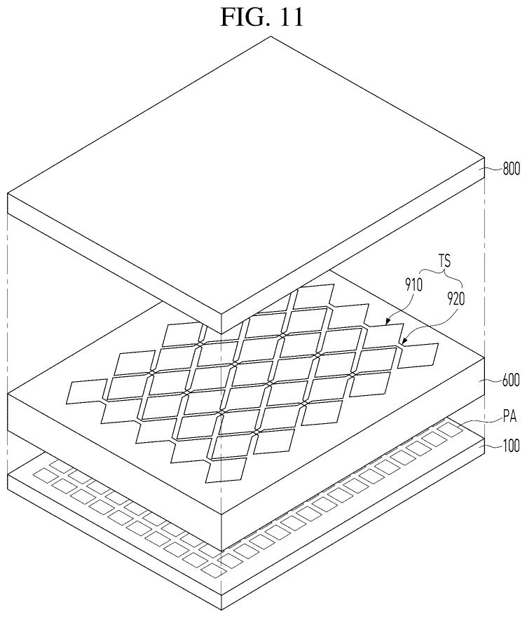

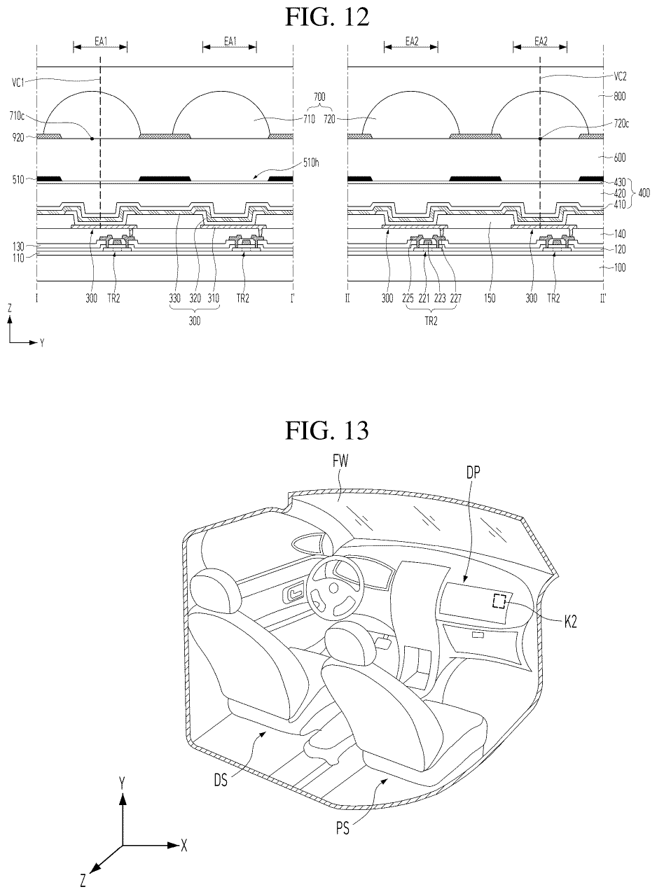

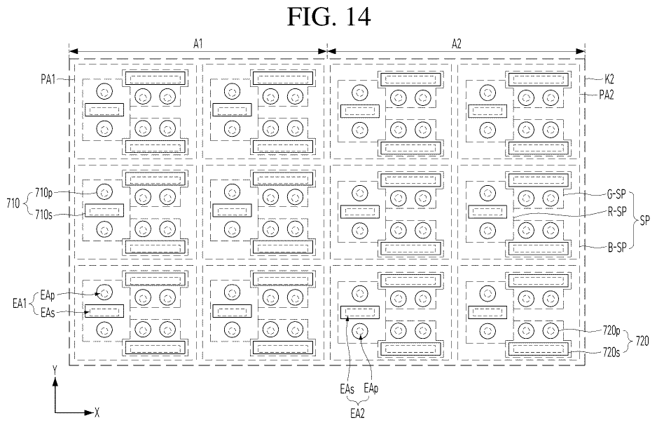

The display apparatus according to the embodiment of the present disclosure is described that the upper barrier pattern 520 includes a same material as the lower barrier pattern 510. However, in the display apparatus according to another embodiment of the present disclosure, the upper barrier pattern 520 can include a different material from the lower barrier pattern 510. For example, in the display apparatus according to another embodiment of the present disclosure, a touch sensor TS sensing a touch of the user and/or a tool can be disposed between the optical insulating layer 600 and the lens planarization layer 800, as shown in FIGS. 11 and 12.

The touch sensor TS can include touch electrodes 910 and bridge electrodes 920 connecting between the touch electrodes 910. The touch electrodes 910 and the bridge electrodes 920 can include a conductive material. The touch electrodes 910 and the bridge electrodes 920 can include a material capable of blocking light. For example, the touch electrodes 910 and the bridge electrodes 920 can include a metal. At least some of the bridge electrodes 920 can include a different material from the touch electrodes 910. For example, at least some of the bridge electrodes 920 can be disposed on a different layer from the touch electrode 910.

A lower surface of each touch electrode 910 toward the device substrate 100 can be in direct contact with the upper surface of the optical insulating layer 600. For example, the touch electrodes 910 can be disposed between the optical insulating layer 600 and the lens planarization layer 800. The touch electrodes 910 can be disposed outside the emission area EA1 and EA2 defined in each pixel area PA. For example, the touch electrodes 910 can be disposed within the non-emission area. An edge of each pixel lens 710 and 720 can overlap with one of the touch electrodes 910. The touch electrodes 910 can overlap with the lower barrier pattern 510. The travelling direction of the light passing through each lower opening can be limited by the touch electrodes 910. For example, in the display apparatus according to another embodiment of the present disclosure, the touch electrodes 910 can function as the upper barrier pattern. That is, in the display apparatus according to another embodiment of the present disclosure, a process of forming the upper barrier pattern can be omitted. Therefore, in the display apparatus according to another embodiment of the present disclosure, the process efficiency can be improved.

In the display apparatus according to another embodiment of the present disclosure, the image realized by the display panel DP can optionally be the driver sitting in the driver seat DS. For example, in the display apparatus according to another embodiment of the present disclosure, the display panel DP can be installed in the front of the passenger seat PS of the car. The display panel DP can realize one of the first image sharing with the driver sitting in the driver seat DS and the second image that is not recognized by the driver. Thus, in the display apparatus according to another embodiment of the present disclosure, accidents due to gaze dispersion of the driver while driving the car can be prevented or at least reduced.

A plurality of sub-pixels SP can be disposed within each pixel area PA1 and PA2. For example, a red sub-pixel R-SP realizing a red color, a green sub-pixel G-SP realizing a green color and a blue sub-pixel B-SP realizing a blue color can be disposed within each pixel area PA1 and PA2. A S-mode emission area EAs and a P-mode emission area EAp can be defined in each sub-pixel SP. The number of the P-mode emission area EAp defined in each sub-pixel SP can be different from the number of the S-mode emission area EAs defined in the corresponding sub-pixel SP. For example, a single S-mode emission area EAs and two P-mode emission areas EAp can be defined within each sub-pixel SP.

A plane of the P-mode emission area EAp can be different from a plane of the S-mode emission area EAs. For example, the S-mode emission area EAs can have a planar shape of a bar extending in the first direction X, and a plane of the P-mode emission area EAp can have a circular shape. The pixel lenses 710 and 720 overlapping with the emission areas EAs and EAp of each sub-pixel SP can include a S-mode pixel lens 710s and 720s having a planar shape corresponding to the S-mode emission area EAs of the corresponding sub-pixel SP and a P-mode pixel lens 710p and 720p having a planar shape corresponding to the P-mode emission area EAp of the corresponding sub-pixel SP. The S-mode emission area EAs and the S-mode pixel lens 710s and 720s of each sub-pixel SP can realize an image having a viewing angle wider than the P-mode emission area EAp and the P-mode pixel lens 710p and 720p of each sub-pixel SP in the first direction X. Thus, in the display apparatus according to another embodiment of the present disclosure, one of the first image by the S-mode emission area EAs and the S-mode pixel lens 710s and 720s of each sub-pixel and the second image by the P-mode emission area EAp and the P-mode pixel lens 710p and 720p of each sub-pixel can be provided. That is, in the display apparatus according to another embodiment of the present disclosure, the first image having a relative wide viewing angle and the second image having a relative narrow viewing angle can be optionally realized. Therefore, in the display apparatus according to another embodiment of the present disclosure, the difference in the color sense of the images having different viewing angles can be minimized.

In the result, the display apparatus according to the embodiments of the present disclosure can comprise the first light-emitting device and the first pixel lens stacked on the first emission area of the device substrate, wherein the lens central point of the first pixel lens can be spaced apart from the emission central portion of the first emission area. Thus, in the display apparatus according to the embodiments of the present disclosure, the light emitted from the first light-emitting device can have the maximum luminance in an inclined direction with respect to a direction perpendicular to the upper surface of the device substrate toward the first pixel lens. Thereby, in the display apparatus according to the embodiments of the present disclosure, the decrease in the quality of the image based on the installation location can be prevented. And, in the display apparatus according to the embodiments of the present disclosure, the low power operation can be possible, and the power consumption can be reduced.

In one embodiment, a display apparatus comprises: a first light-emitting device on a first display area of a device substrate, the first light-emitting device overlapping with a first emission area of the first display area; a second light-emitting device on a second display area of the device substrate, the second light-emitting device overlapping with a second emission area of the second display area; an optical insulating layer on the first light-emitting device and the second light-emitting device, the optical insulating layer overlapping with the first display area and the second display area; a first pixel lens on the optical insulating layer of the first display area, the first pixel lens including a region overlapping with the first emission area; and a second pixel lens on the optical insulating layer of the second display area, the second pixel lens including a region overlapping with the second emission area, wherein a first lens central point of the first pixel lens is spaced apart from a first virtual line passing through a first emission central portion of the first emission area in a direction perpendicular to an upper surface of the device substrate toward the optical insulating layer, and wherein a second lens central point of the second pixel lens is disposed on a second virtual line passing through a second emission central portion of the second emission area in a direction perpendicular to the upper surface of the device substrate.

In one embodiment, the second display area extends along an edge of the first display area.

In one embodiment, the first pixel lens has a planar shape corresponding to a planar shape of the first emission area and the second pixel lens has a planar shape corresponding to a planar shape of the second emission area.

In one embodiment, the planar shape of the second emission area is a same as the planar shape of the first emission area.

In one embodiment, each of the first pixel lens and the second pixel lens has a planar shape of a bar extending in a first direction, and wherein the first lens central point is spaced apart from the first virtual line in a second direction that is different from the first direction.

In one embodiment, the second emission central portion is disposed on a third virtual line that passes through the first emission central portion in the first direction.

In one embodiment, the second pixel lens is on a same layer as the first pixel lens.

In one embodiment, a material of the second pixel lens is a same as a material of the first pixel lens.

In one embodiment, a display apparatus comprises: a device substrate; a bank insulating layer on the device substrate, the bank insulating layer defining a first emission area in a first display area; a first light-emitting device on the first display area of the device substrate, the first light-emitting device overlapping the first emission area; an optical insulating layer on the bank insulating layer and the first light-emitting device, the optical insulating layer overlapping the first light-emitting device and the first display area; an upper barrier pattern on the optical insulating layer, the upper barrier pattern including a first upper opening overlapping with the first emission area and the first light-emitting device; and a first pixel lens on the upper barrier pattern, the first pixel lens including a region overlapping with the first upper opening, wherein the first pixel lens includes a first edge and a second edge opposite to the first edge, wherein an amount of overlap between a first pattern region of the upper barrier pattern and the first edge of the first pixel lens is different from an amount of overlap between a second pattern region of the upper barrier pattern and the second edge.

In one embodiment, a center of the first upper opening is disposed on a virtual line passing through an emission central portion of the first emission area in a direction perpendicular to an upper surface of the device substrate toward the optical insulating layer.

In one embodiment, a cross-section of the first pixel lens in a first direction has a semi-circular shape.

In one embodiment, the first emission area and the first upper opening each have a planar shape of a bar extending in a second direction that is different from the first direction, and wherein the first edge and the second edge of the first pixel lens extend in the second direction.

In one embodiment, the bank insulating layer further defines a second emission area in a second display area that surrounds the first display area, the display apparatus further comprising: a second light-emitting device between the device substrate and the optical insulating layer, the second light-emitting device overlapping with the second emission area; and a second pixel lens on the upper barrier pattern, the second pixel lens including a region overlapping with a second upper opening of the upper barrier pattern, wherein the second pixel lens includes a third edge and a fourth edge on the upper barrier pattern and overlapping with the second emission area, and wherein an amount of overlap between a third pattern region of the upper barrier pattern and the third edge is a same as an amount of overlap between a fourth pattern region of the upper barrier pattern and the fourth edge.

In one embodiment, a size of the second pixel lens is a same as a size of the first pixel lens.

In one embodiment, the third pattern region and the fourth pattern region have a different size than the first pattern region and the second pattern region.

In one embodiment, a display apparatus comprises: a substrate having a first display area including a first emission area and a second display area including a second emission area; a first light emitting device overlapping with the first emission area; a second light emitting device overlapping with the second emission area; a first pixel lens overlapping the first light emitting device and the first emission area; and a second pixel lens overlapping the second light emitting device and the second emission area; wherein a center of the first pixel lens is offset from a center of the first emission area in a plan view of the display apparatus and a center of the second pixel lens overlaps a center of the second emission area in the plan view.

In one embodiment, the display apparatus further comprises: a barrier pattern including a first opening that overlaps the first emission area and the first light emitting device, wherein the barrier pattern include includes a first region and a second region around the first opening, wherein an amount of overlap between the first region and the first pixel lens is different from an amount of overlap between the second region and the first pixel lens.

In one embodiment, the barrier pattern further comprises a second opening that overlaps the second emission area and the second light emitting device, and a third region and a fourth region around the second opening, wherein an amount of overlap between the third region and the second pixel lens is a same as an amount of overlap between the fourth region and the second pixel lens.

In one embodiment, a size of the second pixel lens is a same as a size of the first pixel lens.

In one embodiment, the second pixel lens is on a same layer as the first pixel lens.

What is claimed is:

1. A display apparatus comprising:
a first light-emitting device on a first display area of a device substrate, the first light-emitting device overlapping with a first emission area of the first display area;
a second light-emitting device on a second display area of the device substrate, the second light-emitting device overlapping with a second emission area of the second display area;
an optical insulating layer on the first light-emitting device and the second light-emitting device, the optical insulating layer overlapping with the first display area and the second display area;
a first pixel lens on the optical insulating layer of the first display area, the first pixel lens including a region overlapping with the first emission area; and
a second pixel lens on the optical insulating layer of the second display area, the second pixel lens including a region overlapping with the second emission area,
wherein a first lens central point of the first pixel lens is spaced apart from a first virtual line passing through a first emission central portion of the first emission area in a direction perpendicular to an upper surface of the device substrate toward the optical insulating layer, and
wherein a second lens central point of the second pixel lens is disposed on a second virtual line passing through a second emission central portion of the second emission area in a direction perpendicular to the upper surface of the device substrate.

2. The display apparatus according to claim 1, wherein the second display area extends along an edge of the first display area.

3. The display apparatus according to claim 1, wherein the first pixel lens has a planar shape corresponding to a planar shape of the first emission area and the second pixel lens has a planar shape corresponding to a planar shape of the second emission area.

4. The display apparatus according to claim 3, wherein the planar shape of the second emission area is a same as the planar shape of the first emission area.

5. The display apparatus according to claim 3, wherein each of the first pixel lens and the second pixel lens has a planar shape of a bar extending in a first direction, and
wherein the first lens central point is spaced apart from the first virtual line in a second direction that is different from the first direction.

6. The display apparatus according to claim 5, wherein the second emission central portion is disposed on a third virtual line that passes through the first emission central portion in the first direction.

7. The display apparatus according to claim 1, wherein the second pixel lens is on a same layer as the first pixel lens.

8. The display apparatus according to claim 1, wherein a material of the second pixel lens is a same as a material of the first pixel lens.

9. A display apparatus, comprising:
a device substrate;
a bank insulating layer on the device substrate, the bank insulating layer defining a first emission area in a first display area;
a first light-emitting device on the first display area of the device substrate, the first light-emitting device overlapping the first emission area;
an optical insulating layer on the bank insulating layer and the first light-emitting device, the optical insulating layer overlapping the first light-emitting device and the first display area;
an upper barrier pattern on the optical insulating layer, the upper barrier pattern including a first upper opening overlapping with the first emission area and the first light-emitting device; and
a first pixel lens on the upper barrier pattern, the first pixel lens including a region overlapping with the first upper opening,
wherein the first pixel lens includes a first edge and a second edge opposite to the first edge,
wherein an amount of overlap between a first pattern region of the upper barrier pattern and the first edge of the first pixel lens is different from an amount of overlap between a second pattern region of the upper barrier pattern and the second edge.

10. The display apparatus according to claim 9, wherein a center of the first upper opening is disposed on a virtual line passing through an emission central portion of the first emission area in a direction perpendicular to an upper surface of the device substrate toward the optical insulating layer.

11. The display apparatus according to claim 9, wherein a cross-section of the first pixel lens in a first direction has a semi-circular shape.

12. The display apparatus according to claim 11, wherein the first emission area and the first upper opening each have a planar shape of a bar extending in a second direction that is different from the first direction, and
wherein the first edge and the second edge of the first pixel lens extend in the second direction.

13. The display apparatus according to claim 9, wherein the bank insulating layer further defines a second emission area in a second display area that surrounds the first display area, the display apparatus further comprising:
a second light-emitting device between the device substrate and the optical insulating layer, the second light-emitting device overlapping with the second emission area; and
a second pixel lens on the upper barrier pattern, the second pixel lens including a region overlapping with a second upper opening of the upper barrier pattern,
wherein the second pixel lens includes a third edge and a fourth edge on the upper barrier pattern and overlapping with the second emission area, and
wherein an amount of overlap between a third pattern region of the upper barrier pattern and the third edge is a same as an amount of overlap between a fourth pattern region of the upper barrier pattern and the fourth edge.

14. The display apparatus according to claim 13, wherein a size of the second pixel lens is a same as a size of the first pixel lens.

15. The display apparatus according to claim 13, wherein the third pattern region and the fourth pattern region have a different size than the first pattern region and the second pattern region.

16. A display apparatus, comprising:
a substrate having a first display area including a first emission area and a second display area including a second emission area;
a first light emitting device overlapping with the first emission area;
a second light emitting device overlapping with the second emission area;
a first pixel lens overlapping the first light emitting device and the first emission area;
and a second pixel lens overlapping the second light emitting device and the second emission area;
wherein a center of the first pixel lens is offset from a center of the first emission area in a plan view of the display apparatus and a center of the second pixel lens overlaps a center of the second emission area in the plan view.

17. The display apparatus of claim 16, wherein a planar shape of the second pixel lens is a same as a planar shape of the first pixel lens.

18. The display apparatus of claim 17, wherein the first pixel lens and the second pixel lens have a planar shape of a bar extending in a first direction, and
wherein a center of the first pixel lens overlaps a center of the second pixel lens in the first direction in a plan view.

19. The display apparatus of claim 18, wherein a center of the first pixel lens overlaps a center of the first emission area in a second direction perpendicular to the first direction in a plan view.

20. The display apparatus of claim 18, wherein a center of the first emission area is offset from a center of the second emission area in the first direction in the plan view.
